(19) United States
(12) Patent Application Publication
(10) Pub. No.: US 2023/0131416 A1
(43) Pub. Date: Apr. 27, 2023

(54) IMAGING ELEMENT AND IMAGING DEVICE

(71) Applicant: SONY SEMICONDUCTOR SOLUTIONS CORPORATION, Kanagawa (JP)

(72) Inventor: Katsuhisa KUGIMIYA, Kanagawa (JP)

(73) Assignee: SONY SEMICONDUCTOR SOLUTIONS CORPORATION, Kanagawa (JP)

(21) Appl. No.: 17/914,006

(22) PCT Filed: Feb. 15, 2021
(86) PCT No.: PCT/JP2021/005410

§ 371 Date: Sep. 23, 2022

(30) Foreign Application Priority Data
Mar. 31, 2020 (JP) 2020-065341

(51) Int. Cl. H01L 27/146

(52) U.S. Cl. CPC H01L 27/1463; H01L 27/14621; H01L 27/14623; H01L 27/14627

(57) ABSTRACT

Strength of an imaging element in which separation portions are disposed at boundaries of pixels is improved. The imaging element includes a plurality of pixels, separation portions, light blocking films, and separation portion protection films. The plurality of pixels include photoelectric conversion units that are formed on a semiconductor substrate and perform photoelectric conversion of incident light. The separation portions are disposed at boundaries of the plurality of pixels and separate the photoelectric conversion units from each other. The light blocking films are disposed near the boundaries of the plurality of pixels and block the incident light. The separation portion protection films are disposed adjacent to the separation portions and protect the separation portions.

### TECHNICAL FIELD

The present disclosure relates to an imaging element and an imaging device. More specifically, the present disclosure relates to an imaging element including pixels having separation portions at boundaries thereof and an imaging device using the imaging element.

### BACKGROUND ART

Conventionally, an imaging element configured by disposing pixels that generate image signals on the basis of incident light in a two-dimensional grid pattern is used. In each of the pixels, an on-chip lens that condenses incident light, a color filter that transmits incident light having a predetermined wavelength, and a photoelectric conversion unit formed on a semiconductor substrate to perform photoelectric conversion of the incident light are disposed. For the color filter, three types of color filters that transmit red light, green light, and blue light can be used. In addition, light blocking films that block incident light are disposed at the boundaries of the pixels. These light blocking films are films that block incident light obliquely incident from adjacent pixels. By disposing these light blocking films, the incident light transmitted through the color filters of adjacent pixels can be blocked, and the occurrence of color mixing can be reduced. Here, color mixing is a phenomenon in which an image signal is affected by incident light having a wavelength different from that of a color filter disposed in its own pixel. It is caused by incidence of light transmitted through a color filter of an adjacent pixel.

As such an imaging element, a solid-state imaging element in which light blocking portions made of a metal are disposed has been proposed (see, for example, PTL 1). Each light blocking portion is configured of a metal portion having a shape extending toward a central portion of a pixel array in which pixels are disposed in a two-dimensional grid pattern and a metal portion having a shape extending toward an incident light side. In pixels disposed in the central portion of the pixel array, the light blocking portions are disposed in outer peripheral portions of the pixels. On the other hand, in pixels disposed in an outer peripheral portion of the pixel array, the light blocking portions are disposed at positions shifted from outer peripheral portions of the pixels toward the central portion of the pixel array. Due to influence of a photographing lens that forms an image of a subject on a solid-state imaging element, incident light is obliquely incident on the pixels at the outer peripheral portion of the pixel array. In order to guide the obliquely incident light to the photoelectric conversion unit, in the pixels in the outer peripheral portion, the on-chip lenses and the color filters are disposed to be shifted toward the central portion of the pixel array. In order to achieve alignment with positions of the color filters, the light blocking portions are also disposed at shifted positions.

### CITATION LIST

### Patent Literature

[PTL 1] JP 2017-011207 A

### SUMMARY

### Technical Problem

The above-described conventional technique has a problem that strength of the pixels is lowered. In order to separate the photoelectric conversion units of the pixels, separation portions are disposed on a semiconductor substrate at the boundaries of the pixels. For these separation portions, separation portions that separate the photoelectric conversion units by groove-shaped opening portions surrounding the pixels are used. By disposing insulators in these opening portions, the photoelectric conversion portions can be separated from each other. However, when such a separation portion is applied to the above-described conventional technique, there is a problem that strength of the imaging element is lowered due to the opening portions formed in the semiconductor substrate.

The present disclosure has been made in view of the above-described problems, and an object thereof is to improve strength of an imaging element in which separation portions are disposed at boundaries of pixels.

### Solution to Problem

The present disclosure has been made to solve the above-mentioned problems, and a first aspect thereof is an imaging element including: a plurality of pixels including photoelectric conversion units that are formed on a semiconductor substrate and perform photoelectric conversion of incident light; separation portions that are disposed at boundaries of the plurality of pixels and separate the photoelectric conversion units from each other; light blocking films that are disposed near the boundaries of the plurality of pixels and block the incident light; and separation portion protection films that are disposed adjacent to the separation portions and protect the separation portions.

Also, in the first aspect, the separation portions may be disposed in opening portions formed in the semiconductor substrate.

Also, in the first aspect, the separation portions may include an insulating material disposed in the opening portions.

Also, in the first aspect, voids may be disposed in the separation portion protection films.

Also, in the first aspect, color filters that are disposed in the plurality of pixels and transmit incident light having predetermined wavelengths among the incident lights may be further provided.

Also, in the first aspect, on-chip lenses that are disposed in the plurality of pixels and condense the incident light on the photoelectric conversion units may be further provided.

Also, in the first aspect, the light blocking films may be disposed at shifted positions in accordance with angles of incidence of the incident light.

Also, in the first aspect, the separation portion protection films may be disposed adjacent to the light blocking films.

Also, in the first aspect, the light blocking films may be disposed to overlap the separation portion protection films.

Also, in the first aspect, the pixels may be configured in rectangular shapes in a plan view.

Also, in the first aspect, the separation portion protection films may be disposed near sides of the rectangular shapes.

Also, in the first aspect, the separation portion protection films may be disposed near corners of the rectangular shapes.

Also, in the first aspect, the separation portion protection films may be made of an insulating material.

Also, in the first aspect, the separation portion protection films may be made of a silicon compound.

Also, in the first aspect, the separation portion protection films may be made of a resin.

Also, in the first aspect, the separation portion protection films may be made of a metal.

A second aspect of the present disclosure is an imaging device including: a plurality of pixels including photoelectric conversion units that are formed on a semiconductor substrate and perform photoelectric conversion of incident light; separation portions that are disposed at boundaries of the plurality of pixels and separate the photoelectric conversion units from each other; light blocking films that are disposed near the boundaries of the plurality of pixels and block the incident light; separation portion protection films that are disposed adjacent to the separation portions and protect the separation portions; and a processing circuit that processes image signals generated on the basis of the photoelectric conversion.

According to the aspects of the present disclosure, the separation portion protection films are disposed adjacent to the separation portions. It is assumed that the separation portions are protected by the separation portion protection films.

### BRIEF DESCRIPTION OF DRAWINGS

FIG. 1 is a diagram showing a configuration example of an imaging element according to an embodiment of the present disclosure.

FIG. 2 is a plan view showing a configuration example of the imaging element according to the embodiment of the present disclosure.

FIG. 3 is a diagram showing a configuration example of pixels according to a first embodiment of the present disclosure.

FIG. 4 is a diagram showing a configuration example of a separation portion protection film according to the first embodiment of the present disclosure.

FIG. 5 is a diagram showing a configuration of a separation portion according to a comparative example of the embodiment of the present disclosure.

FIG. 6 is a plan view showing a configuration example of the pixels according to the first embodiment of the present disclosure.

FIG. 7 is a diagram showing a method for manufacturing the imaging element according to the first embodiment of the present disclosure.

FIG. 8 is a diagram showing the method for manufacturing the imaging element according to the first embodiment of the present disclosure.

FIG. 9 is a plan view showing configuration of pixels according to a modified example of the first embodiment of the present disclosure.

FIG. 10 is a plan view showing a configuration example of pixels according to a second embodiment of the present disclosure.

FIG. 11 is a diagram showing a configuration example of a separation portion protection film according to a third embodiment of the present disclosure.

FIG. 12 is a diagram showing another configuration example of the separation portion protection film according to the third embodiment of the present disclosure.

FIG. 13 is a diagram showing a configuration example of pixels according to a fourth embodiment of the present disclosure.

FIG. 14 is a block diagram showing a schematic configuration example of a camera which is an example of an imaging device to which the present technique may be applied.

### DESCRIPTION OF EMBODIMENTS

Next, forms for implementing the present disclosure (hereinafter referred to as embodiments) will be described with reference to the figures. In the following figures, the same or similar portions are denoted by the same or similar reference signs. In addition, the embodiments will be described in the following order.
1. First embodiment
2. Second embodiment
3. Third embodiment
4. Fourth embodiment
5. Example of application to camera

### 1. First Embodiment

### Configuration of Imaging Element

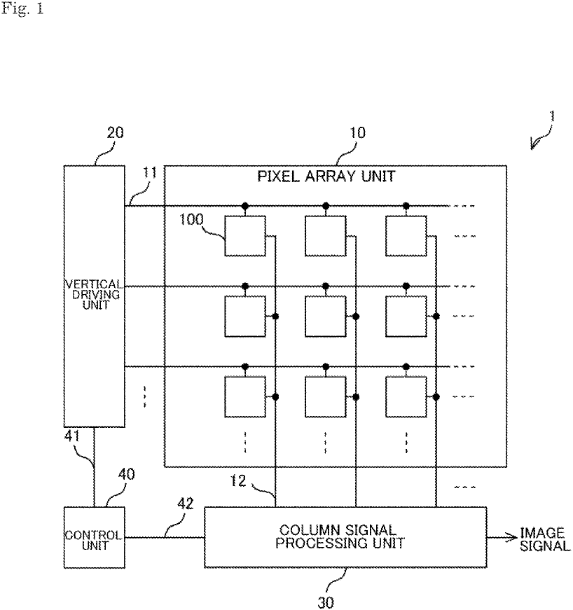

FIG. 1 is a diagram showing a configuration example of an imaging element according to an embodiment of the present disclosure. The imaging element 1 in the figure includes a pixel array unit 10, a vertical driving unit 20, a column signal processing unit 30, and a control unit 40.

The pixel array unit 10 is configured by disposing pixels 100 in a two-dimensional grid pattern. Here, the pixels 100 generate image signals in response to radiated light. These pixels 100 have photoelectric conversion units that generate charges in response to the radiated light. In addition, the pixels 100 further include pixel circuits. The pixel circuits generate image signals based on the charges generated by the photoelectric conversion units. Generation of the image signals is controlled by control signals generated by the vertical driving unit 20, which will be described later. Signal lines 11 and 12 are disposed in an XY matrix form in the pixel array unit 10. The signal line 11 is a signal line through which the control signals for the pixel circuits of the pixels 100 are transmitted, is disposed for each row of the pixel array unit 10, and is commonly wired for pixels 100 disposed in each row. The signal line 12 is a signal line through which the image signals generated by the pixel circuits of the pixels 100 are transmitted, is disposed for each column of the pixel array unit 10, and is commonly wired for pixels 100 disposed in each column. The photoelectric conversion units and the pixel circuits are formed on a semiconductor substrate.

The vertical driving unit 20 generates the control signals for the pixel circuits of the pixels 100. The vertical driving unit 20 transmits the generated control signals to the pixels 100 through the signal line 11 in the figure. The column signal processing unit 30 processes the image signals generated by the pixels 100. The column signal processing unit 30 performs processing of the image signals transmitted from the pixels 100 through the signal line 12 in the figure. The processing in the column signal processing unit 30 corresponds to, for example, analog-to-digital conversion of converting analog image signals generated in the pixels 100 into digital image signals. The image signals processed by the column signal processing unit 30 are output as image signals of the imaging element 1. The control unit 40 controls the overall imaging element 1. The control unit 40 generates and outputs control signals for controlling the vertical driving unit 20 and the column signal processing unit 30, thereby performing control of the imaging element 1. The control signals generated by the control unit 40 are transmitted to the vertical driving unit 20 and the column signal processing unit 30 through signal lines 41 and 42. The column signal processing unit 30 is an example of a processing circuit described in the claims.

### Configuration of Pixel Array Unit

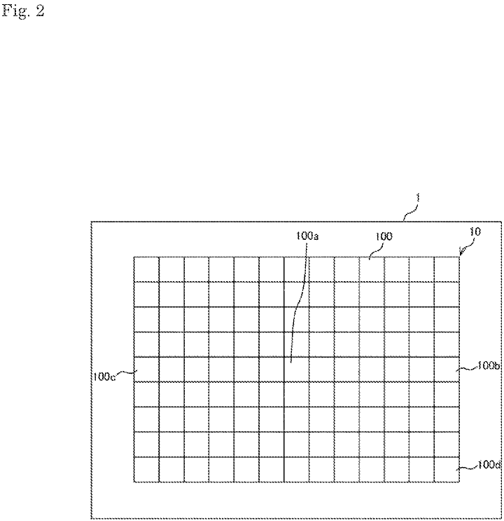

FIG. 2 is a plan view showing a configuration example of the imaging element according to the embodiment of the present disclosure. The figure is a plan view showing a configuration example of the imaging element 1. Rectangles of the pixel array unit 10 of the imaging element 1 in the figure represents the pixels 100. In this way, the pixels 100 are arranged in a two-dimensional grid pattern in the pixel array unit 10. Incident light from a subject is substantially vertically incident on the pixels 100 (a pixel 100a) disposed in a central portion of the pixels 100 of the pixel array unit 10. On the other hand, the incident light is obliquely incident on the pixels at a peripheral edge portion of the pixel array unit 10. This is because, as described above, a photographing lens that forms an image of the subject is disposed outside the imaging element 1, and the imaging element 1 is disposed at a position at which an optical axis of the photographing lens comes to the central portion of the pixel array unit 10. The incident light is incident on the rightmost pixel 100b of the pixel array unit 10 from an obliquely left direction in the figure with respect to the vertical direction, and the incident light is incident on the leftmost pixel 100c from an obliquely right direction in thefigure with respect to the vertical direction. The incident light is incident on a lower right pixel 100d in the figure obliquely from an upper left direction in the figure with respect to the vertical direction.

### Configuration of Pixels

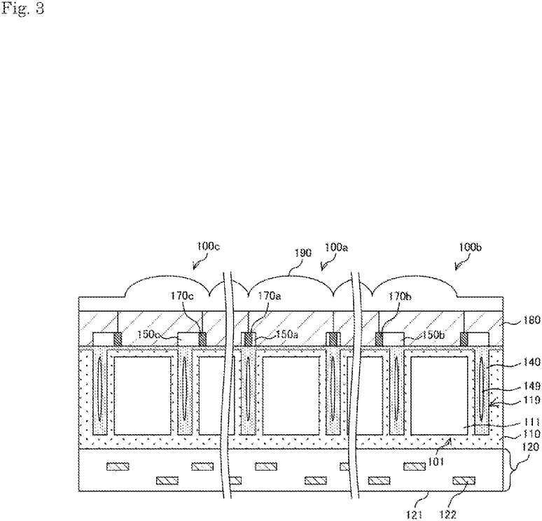

FIG. 3 is a diagram showing a configuration example of pixels according to a first embodiment of the present disclosure. The figure is a schematic cross-sectional view showing a configuration example of the pixels 100. The figure is a cross-sectional view of the pixel array unit 10 along a line passing through the pixels 100a and 100b and the pixel 100c in FIG. 2 and a diagram showing a configuration example of the pixels 100a, 100b, and 100c. Each of the pixels 100 includes a semiconductor substrate 110, a wiring region 120, a separation portion 140, a separation portion protection film 150, a light blocking film 170, a color filter 180, and an on-chip lens 190. Also, the pixels 100a, 100b, and 100c can have the same configuration except for the separation portion protection film 150, the light blocking film 170, the color filter 180, and the on-chip lens 190.

The semiconductor substrate 110 is a semiconductor substrate on which diffusion regions of elements such as photoelectric conversion units and pixel circuits of the pixels 100 are disposed. The element such as the photoelectric conversion unit is disposed in a well region formed in the semiconductor substrate 110. For convenience, it is assumed that the semiconductor substrate 110 in the figure is formed in a p type well region. By forming an n type semiconductor region in the p type well region, a diffusion region of an element can be disposed. In the figure, a photoelectric conversion unit 101 is shown as an example. The photoelectric conversion unit 101 in the figure is configured of an n type semiconductor region 111. Specifically, a photodiode configured by a pn junction between the n type semiconductor region 111 and the p type well region therearound corresponds to the photoelectric conversion unit 101.

The wiring region 120 is a region in which wiring that is disposed on a front surface side of the semiconductor substrate 110 and transmits a signal to an element formed on the semiconductor substrate 110 is formed. The wiring region 120 in the figure includes a wiring layer 122 and an insulating layer 121. The wiring layer 122 is wiring that transmits a signal to an element or the like. The wiring layer 122 can be made of a metal such as copper (Cu), tungsten (W), or the like. The insulating layer 121 insulates the wiring layer 122. The insulating layer 121 can be made of an insulating material such as silicon oxide (SiO₂) or silicon nitride (SiN).

The separation portion 140 is disposed on the semiconductor substrate 110 at a boundary of each of the pixels 100 to separate the pixels 100 from each other. The separation portion 140 in the figure is formed in a shape that surrounds the semiconductor substrate 110 of each of the pixels 100 and electrically separates the pixels 100 from each other. The separation portion 140 separates photoelectric conversion units 101 from each other. This makes it possible to prevent the inflow of charges from photoelectric conversion units 101 of adjacent pixels 100 and to reduce the generation of noise. Further, the separation portion 140 can also prevent incidence of light from the adjacent pixels 100. The separation portion 140 in the figure can be disposed in a groove-shaped opening portion 119 formed in the semiconductor substrate 110. The opening portion 119 represents an example formed in a shape that is formed on a back surface side of the semiconductor substrate 110 and a bottom portion thereof reaches the vicinity of the front surface side of the semiconductor substrate 110.

The separation portion 140 can be made of an insulating material. For example, it can be made of an inorganic material such as SiO₂, SiN, or carbon (C)-containing silicon oxide (SiOC), or an organic material such as a resin. By disposing the insulating material in the opening portion 119 formed on the back surface side of the semiconductor substrate 110, the separation portion 140 can be formed. When the insulating material is disposed, a void 149 can be formed in a central portion of the separation portion 140. The opening portion 119 is closed by a material film of the separation portion 140 before the opening portion 119 is filled with the material film of the separation portion 140, so that the void 149 can be formed. Since the void 149 has a lower relative permittivity, the incident light can be reflected at an interface with the material film of the separation portion 140. Thus, the occurrence of color mixing can be further reduced.

Further, the separation portion 140 can also be made of a metal such as tungsten (W), aluminum (Al), titanium (Ti), cobalt (Co), ruthenium (Ru), or iridium (Ir). In addition, the separation portion 140 can also be made of a semiconductor material such as polycrystalline silicon.

Further, a fixed charge film 131 and an insulating film 132 (not shown) can be disposed on the back surface side of the semiconductor substrate 110 including the opening portion 119. The fixed charge film 131 is a film made of a dielectric having a negative fixed charge. By disposing the fixed charge film 131, influence of a trap level formed near an interface of the semiconductor substrate 110 can be reduced. For the fixed charge film 131, for example, a film of hafnium oxide (HfO₂) can be used. The insulating film 132 is a film that insulates the back surface side of the semiconductor substrate 110. In addition, the insulating film 132 protects the back surface side of the semiconductor substrate 110. The insulating film 132 can be made of an insulating material such as SiO₂ or SiN. Also, a protection film 141 is further disposed on each of the pixels 100 in the figure. The protection film 141 is a film made of a material of the separation portion 140.

The color filter 180 is an optical filter that transmits incident light having a predetermined wavelength among the incident light. For the color filter 180, for example, a color filter that transmits red light, green light, or blue light can be used. A color filter 180 corresponding to any of these three wavelengths can be disposed on each of the pixels 100.

The on-chip lens 190 is a lens that condenses the incident light. The on-chip lens 190 is formed in a hemispherical shape and condenses the incident light on the photoelectric conversion units 101. The on-chip lens 190 can be made of an inorganic material such as SiN, an organic material such as an acrylic resin, or the like. Also, a region of a lower layer below the hemispherical lens portion constituting the on-chip lens 190 constitutes the protection film that protects a back surface of each of the pixels 100. A surface of the protection film on which the on-chip lens 190 is formed is further planarized.

The light blocking film 170 blocks the incident light. The light blocking film 170 is disposed near a boundary of each of the pixels 100 on the back surface side of the semiconductor substrate 110 and blocks the incident light. The light blocking film 170 in the figure is disposed in a lower layer below the color filter 180. As shown in the figure, a plurality of pixels are disposed adjacent to each other in the pixel array unit 10. The light blocking film 170 blocks the incident light that is obliquely incident on the pixels 100 and is transmitted through different types of color filters 180 of the adjacent pixels 100. Thus, the occurrence of color mixing can be reduced. The light blocking film 170 can be made of, for example, a metal such as W, Al, Ti, Co, Ru, or Ir.

The light blocking film 170, the color filter 180, and the on-chip lens 190 are disposed at shifted positions in accordance with positions of the pixels 100 in the pixel array unit 10. As described above, the incident light from the subject is obliquely incident on the pixels 100 at the peripheral edge portion of the pixel array unit 10. In order to condense the obliquely incident light on the photoelectric conversion unit, the color filter 180 and the on-chip lens 190 are disposed to be shifted toward the central portion of the pixel array unit 10. Similarly, the light blocking film 170 is also disposed to be shifted toward the central portion of the pixel array unit 10. This is to prevent blocking of the incident light condensed by the on-chip lens 190 disposed to be shifted. An angle of incidence thereof on the pixels 100 increases in accordance with a distance from the optical axis of the photographing lens. Normally, the optical axis of the photographing lens is disposed at the central portion of the pixel array unit 10. For this reason, the angle of incidence is substantially 0 on the pixels 100 at the central portion of the pixel array unit 10, and the angle of incidence increases toward the peripheral edge portion of the pixel array unit 10.

The light blocking film 170, the color filter 180, and the on-chip lens 190 are disposed at positions shifted in accordance with the angle of incidence. The pixels 100a, 100b, and 100c in the figure represent this state. A color filter 180a and an on-chip lens 190a of the pixel 100a are disposed in a central portion of the pixel 100a. A color filter 180b and an on-chip lens 190b of the pixel 100b are disposed to be shifted left in the figure. A color filter 180c and an on-chip lens 190c of the pixel 100c are disposed to be shifted right in the figure. The processing of shifting the color filter 180 or the like in accordance with the angle of incidence of the incident light is called pupil correction. A light blocking film 170a of the pixel 100a is disposed at a boundary of the pixel, a light blocking film 170b of the pixel 100b is disposed at a position shifted left in the figure from a boundary of the pixel, and a light blocking film 170c of the pixel 100c is disposed at a position shifted right in the figure from a boundary of the pixel. As described above, for the pupil correction, the light blocking film 170 is disposed at a position separated from the separation portion 140 in the pixels 100b and 100c at the peripheral edge portion of the pixel array unit 10.

The separation portion protection film 150 is disposed adjacent to the separation portion 140 and protects the separation portion 140. The separation portion protection film 150 in the figure is disposed on the back surface side of the semiconductor substrate 110 and is disposed adjacent to the separation portion 140 via the above-mentioned protection film 141. As described above, the separation portion 140 is disposed in the opening portion 119 formed in the semiconductor substrate. Strength of the semiconductor substrate 110 is reduced due to the opening portion 119. When a stress is applied to the opening portion 119 in a manufacturing process or the like of the imaging element 1, cracks may be formed in the semiconductor substrate 110 at the bottom portion of the opening portion 119. In addition, cracks may occur at a bottom portion of the separation portion 140. When the void 149 is formed in the separation portion 140 as described above, cracks are likely to occur in the separation portion 140 at an end portion of the void 149. Such cracks become defects in the semiconductor substrate 110 and cause a dark current.

Accordingly, the separation portion protection film 150 is disposed to reduce expansion of the opening portion 119 and reduce concentration of the stress on the bottom portion of the separation portion 140. Thus, strength of the separation portion 140 can be improved, and damage to the separation portion 140 can be prevented. The separation portion protection film 150 can be made of an insulating material. For example, the separation portion protection film 150 can be made of a silicon compound such as SiO₂ or SiN. In addition, for example, the separation portion protection film 150 can be made of a resin. The separation portion protection film 150 in the figure represents an example made of SiO₂. Further, the separation portion protection film 150 is preferably configured to have a film thickness of 10 nm or more. This is so that the strength of the separation portion 140 can be further improved. The separation portion protection film 150 can be disposed adjacent to the light blocking film 170.

### Configuration of Separation Portion Protection Film

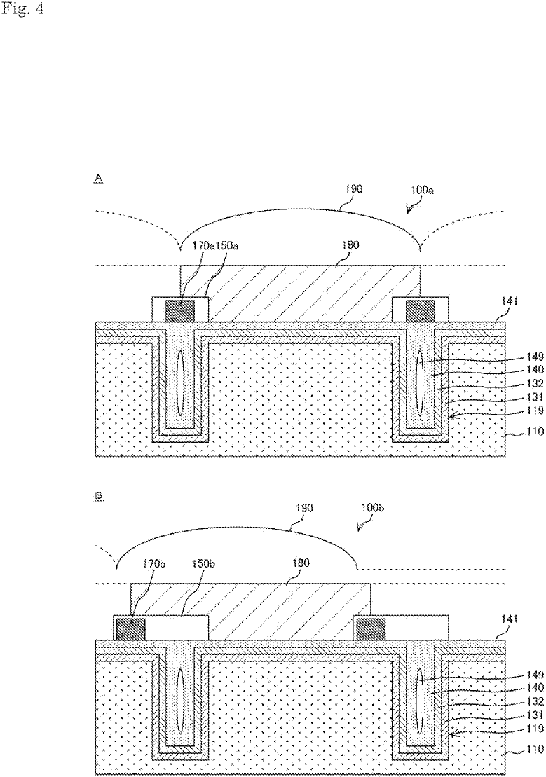

FIG. 4 is a diagram showing a configuration example of the separation portion protection film according to the first embodiment of the present disclosure. The figure is a cross-sectional view showing a configuration example of the separation portion protection film 150 and is an enlarged view of a boundary portion of the pixels 100 described in FIG. 3. A in the figure represents a configuration example of the pixel 100a, and B in the figure represents a configuration example of the pixel 100b.

As described above, the separation portion 140 is disposed in the opening portion 119 formed on the back surface side of the semiconductor substrate 110. The fixed charge film 131 and the insulating film 132 are laminated and disposed on the back surface side of the semiconductor substrate 110. The fixed charge film 131 and the insulating film 132 are also disposed in the opening portion 119. The separation portion 140 is disposed adjacent to the insulating film 132. Further, the protection film 141 is disposed on the back surface side of the semiconductor substrate 110. The protection film 141 can be configured of a film made of the same material as the separation portion 140 and can be formed at the same time as the separation portion 140. The void 149 is formed in the central portion of the separation portion 140. Also, either one of the insulating film 132 and the protection film 141 may be omitted.

In A of the figure, the color filter 180 and the on-chip lens 190 are disposed at the central portion of the pixel 100a. The light blocking film 170a is disposed at a boundary of the pixel 100a. For this reason, the light blocking film 170a is disposed adjacent to the separation portion 140. A separation portion protection film 150a can be formed in a shape including the light blocking film 170a. The light blocking film 170a can be protected by covering the light blocking film 170a with the separation portion protection film 150a.

In B of the figure, the color filter 180 and the on-chip lens 190 are disposed at positions shifted in the right direction in the figure from a central portion of the pixel 100b. The light blocking film 170b is located near a boundary of the pixel 100b and is disposed at a position shifted from the boundary in the right direction in the figure. For this reason, the light blocking film 170b is disposed near the separation portion 140. The separation portion protection film 150b can be disposed adjacent to the separation portion 140 and can be disposed adjacent to the light blocking film 170b. In B of the figure, the separation portion protection film 150b can be formed in a shape extending to a position adjacent to the light blocking film 170b. Further, similarly to A of the figure, the separation portion protection film 150b can be formed in shape including the light blocking film 170b.

Also, the pixel 100c described in FIG. 3 can be formed in a shape in which left and right sides of the pixel 100b of b in the figure are inverted.

### Effects of Separation Portion Protection Film

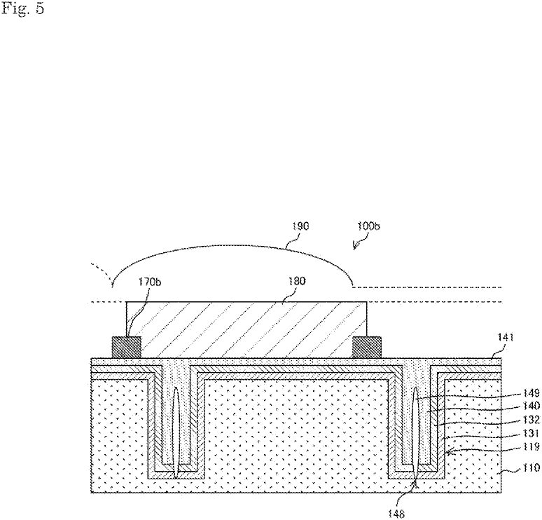

FIG. 5 is a diagram showing a configuration of a separation portion according to a comparative example of the embodiment of the present disclosure. The figure is a figure showing, as a comparative example, a configuration of the separation portion of the pixel 100b in which the separation portion protection film 150 is omitted. As described above, since the light blocking film 170b is disposed at the position shifted from the boundary of the pixel 100b, it is disposed at the position separated from the separation portion 140. A member that closes the opening portion 119 of the separation portion 140 is not disposed, and thus, when a stress of expanding the opening portion 119 is applied, cracks occur in the separation portion 140 or the like adjacent to the bottom portion of the void 149. A crack 148 in the figure shows this state. Defects are formed in the semiconductor substrate 110 near an end portion of the crack 148 and the dark current increases. By disposing the separation portion protection film 150, it is possible to prevent concentration of the stress on the opening portion 119 and prevent occurrence of the crack 148 and the like.

### Configuration of Light Blocking Film and Separation Portion Protection Film

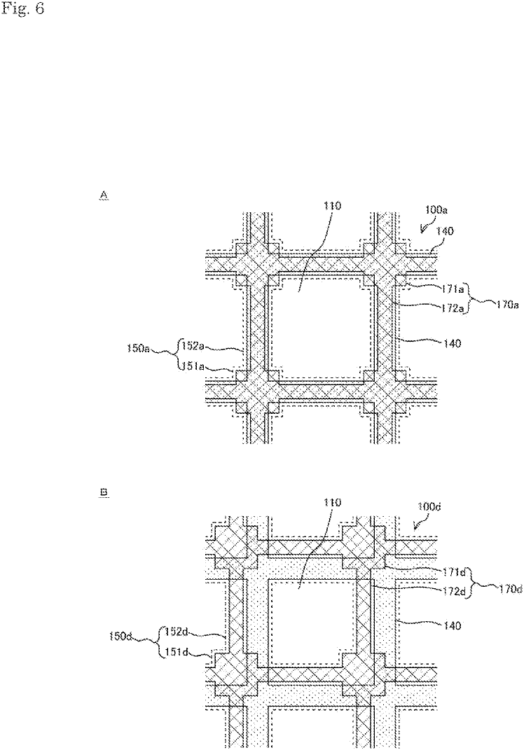

FIG. 6 is a plan view showing a configuration example of the pixels according to the first embodiment of the present disclosure. The figure is a plan view showing a configuration example of the light blocking film 170 and the separation portion protection film 150. A in the figure represents a configuration example of the light blocking film 170 or the like of the pixel 100a, and B in the figure represents a configuration example of the pixel 100d described in FIG. 2. In the figure, the dot-hatched region represents a region of the separation portion 140. The shade-hatched region represents a region of the light blocking film 170. The broken line region represents a region of the separation portion protection film 150.

In the figure, the light blocking film 170 can be formed in different shapes at corners and sides of the pixels 100. Light blocking films 171 and 172 in the figure represent light blocking films 170 near corners and sides of the pixels 100. The light blocking films 171 and 172 represent examples of being formed into square and rectangular shapes in a plan view. The light blocking film 171 can be formed in a rectangular shape having a width wider than that of the light blocking film 172 in a plan view. For example, the light blocking film 171 can be configured to have a size wider than that of the separation portion 140 at corners of the pixels 100.

Further, the separation portion protection film 150 can also be formed in different shapes at corners and sides of the pixels 100. Separation portion protection films 151 and 152 in the figure represent separation portion protection films 150 near corners and sides of the pixels 100. Similarly to the light blocking film 170 described above, the separation portion protection films 151 and 152 represent examples of being formed into square and rectangular shapes in a plan view.

Light blocking films 171a and 172a are disposed on the pixel 100a in A of the figure. These are disposed at the boundary of the pixel 100a and disposed adjacent to the separation portion 140. Separation portion protection films 151a and 152a are formed in shapes for covering the light blocking films 171a and 172a, respectively.

Light blocking films 171d and 172d are disposed on the pixel 100d in B of the figure. These are disposed be shifted in an upper left direction of the figure with respect to the boundary of the pixel 100d. Separation portion protection films 151d and 152d are formed in shapes in which respective end portions thereof are extended to cover the light blocking films 171d and 172d.

### Method for Manufacturing Imaging Element

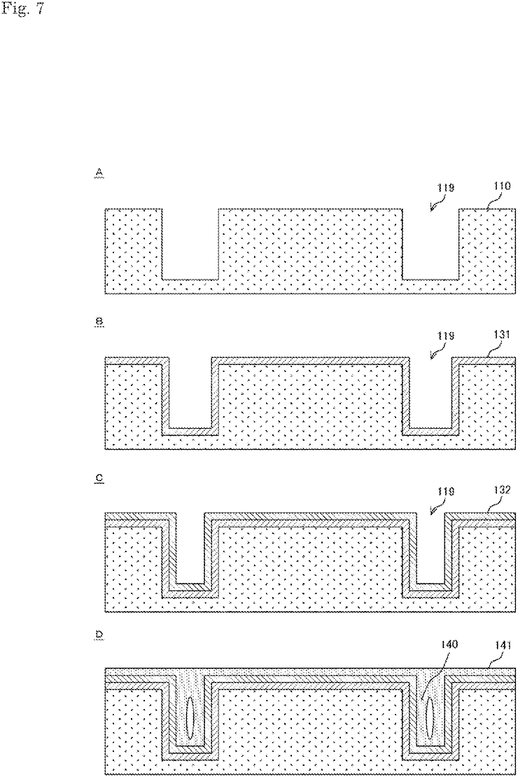

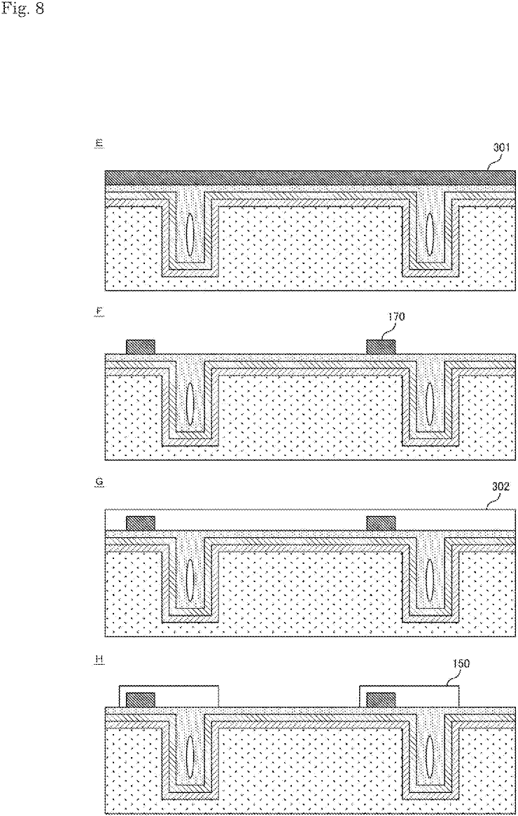

FIGS. 7 and 8 are diagrams showing a method of manufacturing the imaging element according to the first embodiment of the present disclosure. FIGS. 7 and 8 are diagrams showing a manufacturing process of the imaging element 1. Also, FIGS. 7 and 8 are enlarged views of a portion of the pixel 100b. The manufacturing process of the imaging element 1 will be described by taking the pixel 100b as an example.

First, a well region, a semiconductor region (the semiconductor region 111), and the like are formed on the semiconductor substrate 110, and the wiring region 120 is formed on the front surface side of the semiconductor substrate 110. Next, the top and bottom of the semiconductor substrate 110 are inverted, and the back surface side of the semiconductor substrate 110 is ground to reduce the thickness. Next, the opening portion 119 is formed on the back surface side of the semiconductor substrate 110 (A in FIG. 7). This can be performed by performing dry etching of the back surface side of the semiconductor substrate 110.

Next, the fixed charge film 131 is disposed on the back surface side of the semiconductor substrate 110 including the opening portion 119 (B in FIG. 7). This can be performed by, for example, chemical vapor deposition (CVD).

Next, the insulating film 132 is formed and laminated on the fixed charge film 131 (C in FIG. 7). This can be performed by, for example, CVD.

Next, the separation portion 140 is disposed in the opening portion 119 (D in FIG. 7). This can be performed by, for example, disposing an SiO₂ film on the back surface side of the semiconductor substrate 110 including the opening portion 119. The arrangement of the SiO₂ film can be performed by, for example, CVD. At this time, the void 149 is formed in the central portion of the separation portion 140. Further, the protection film 141 is disposed on the back surface side of the semiconductor substrate 110.

A material film 301 of the light blocking film 170 is disposed on the back surface side of the semiconductor substrate 110 (E in FIG. 8). This can be performed by, for example, forming a W film using CVD or the like.

Next, the light blocking film 170 is formed by etching the material film 301 (F in FIG. 8). At this time, the light blocking film 170 is disposed to be sifted for the pupil correction.

Next, the material film 302 of the separation portion protection film 150 is disposed on the back surface side of the semiconductor substrate 110 (G in FIG. 8). This can be performed by, for example, forming an SiO₂ film using CVD or the like and flattening the surface. Also, the SiO₂ film can be flattened by, for example, chemical mechanical polishing (CMP).

Next, the material film 302 is etched to form the separation portion protection film 150 (H in FIG. 8).

After that, the imaging element 1 can be manufactured by disposing the color filter 180 and the on-chip lens 190 in order.

### Modified Examples

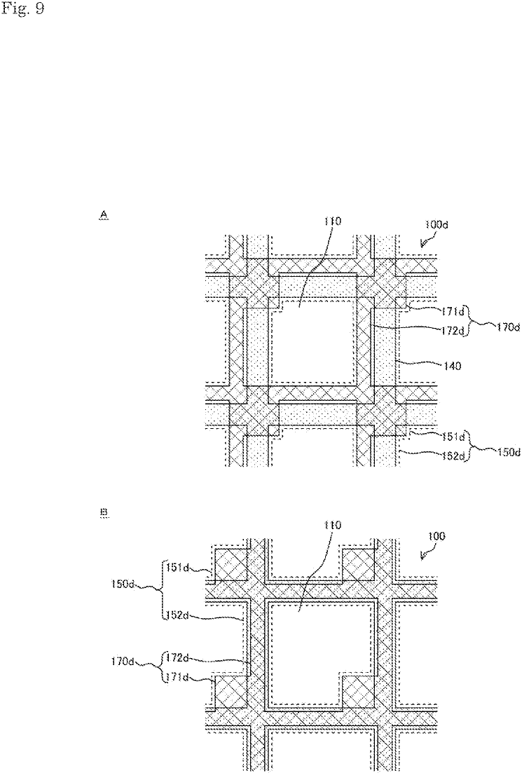

FIG. 9 is a plan view showing a configuration of pixels according to a modified example of the first embodiment of the present disclosure. Similarly to FIG. 6, the figure is a plan view showing a configuration example of the light blocking film 170 and the separation portion protection film 150. The method of pupil correction is different from that of the light blocking film 170 in FIG. 6. The figure is a diagram showing a configuration example of the pixel 100d.

A in the figure shows a configuration in which the pupil correction is performed on the light blocking film 172d among the light blocking films 171d and 172d. The light blocking film 172d disposed on a side of the pixel 100d is disposed to be shifted in an upper left direction of the figure. On the other hand, B in the figure shows a configuration in which the pupil correction is performed on the light blocking film 171d among the light blocking films 171d and 172d. The light blocking film 171d disposed at a corner of the pixel 100d is disposed to be shifted in the upper left direction of the figure.

In either case, the separation portion protection films 151d and 152d can be formed in shapes in which they are disposed adjacent to the separation portion 140 and include the light blocking films 171 and 172.

As described above, in the imaging element 1 of the first embodiment of the present disclosure, the separation portion protection film 150 is disposed adjacent to the separation portion 140 disposed at the boundary of the pixel 100, so that the strength of the separation portion 140 can be improved. Thus, the strength of the imaging element 1 can be improved.

### 2. Second Embodiment

In the imaging element 1 of the first embodiment described above, the separation portion protection film 150 having a shape surrounding the pixel 100 has been disposed. On the other hand, an imaging element 1 of a second embodiment of the present disclosure is different from the above-mentioned first embodiment in that any portion of the separation portion protection film 150 at the corners and sides of the pixels 100 is omitted.

### Configuration of Separation Portion Protection Film

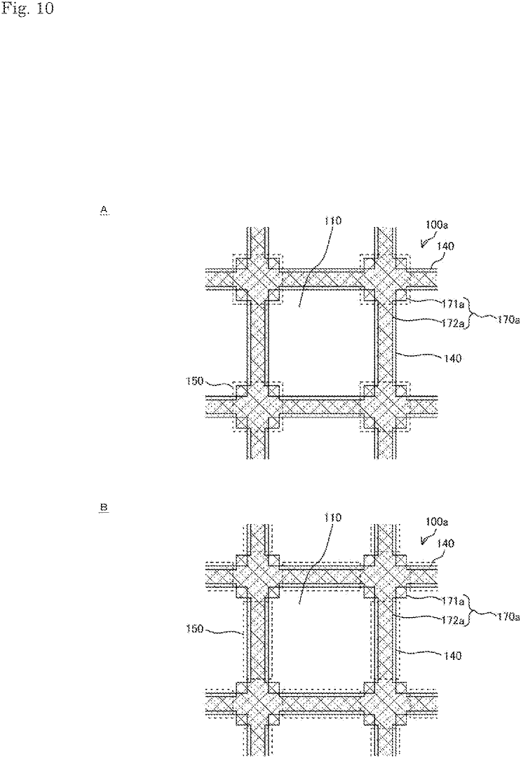

FIG. 10 is a plan view showing a configuration example of pixels according to the second embodiment of the present disclosure. Similarly to FIG. 6, the figure is a plan view showing a configuration example of the light blocking film 170 and the separation portion protection film 150. It is different from the pixels 100 in FIG. 6 in that the separation portion protection film 150 is disposed at corners or sides of the pixels 100.

The figure is a diagram showing a configuration example of the pixel 100a. A in the figure represents the separation portion protection film 150 disposed near a corner of the pixel 100a. The separation portion protection film 150 in A of the figure is formed in a shape including the light blocking film 171a.

B in the figure represents the separation portion protection film 150 disposed near a side of the pixels 100a. The separation portion protection film 150 in B of the figure is formed in a shape including the light blocking film 172a.

As described above, in the pixel 100 in the figure, the separation portion protection film 150 near any of the corners and sides of the pixels 100 is omitted.

Since other configurations of the imaging element 1 are the same as those of the imaging element 1 described in the first embodiment of the present disclosure, the description thereof will be omitted.

As described above, in the imaging element 1 of the second embodiment of the present disclosure, the separation portion protection film 150 near any of the corners and sides of the pixels 100 is omitted. Thus, the configuration of the pixels 100 can be simplified.

### 3. Third Embodiment

The imaging element 1 of the first embodiment described above uses the separation portion protection film 150 made of an insulating material. On the other hand, an imaging element 1 of a third embodiment of the present disclosure is different from the above-mentioned first embodiment in that the separation portion protection film 150 made of a metal is used.

### Configuration of Separation Portion Protection Film

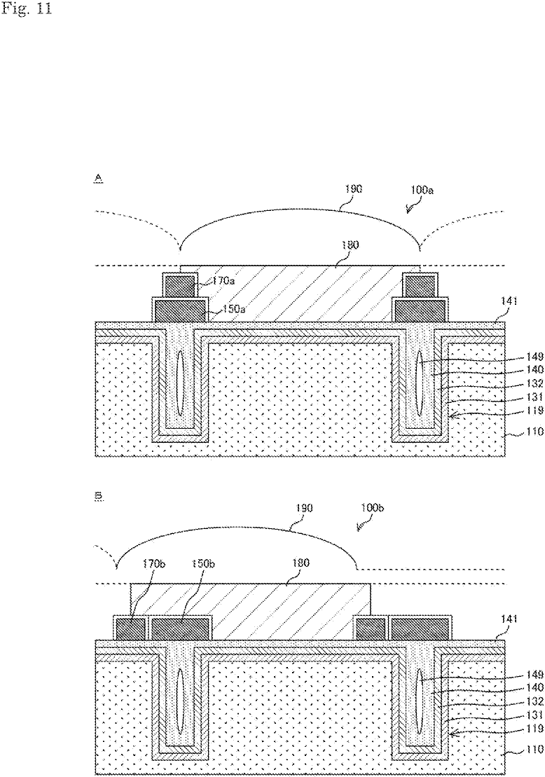

FIG. 11 is a diagram showing a configuration example of the separation portion protection film according to the third embodiment of the present disclosure. Similarly to FIG. 4, the figure is a cross-sectional view showing a configuration example of the separation portion protection film 150. It is different from the separation portion protection film 150 in FIG. 4 in that the separation portion protection film 150 made of a metal is disposed.

The separation portion protection film 150 in the figure can be made of the same material as the light blocking film 170. Specifically, the separation portion protection film 150 in the figure can be made of, for example, a metal such as W, Al, Ti, Co, Ru, or Ir. Further, similarly to the light blocking film 170, a protection film made of SiO₂ or the like can be disposed on a front surface of the separation portion protection film 150.

Also, in the pixel 100 in the figure, the light blocking film 170 is disposed after the separation portion protection film 150 is disposed on the back surface side of the semiconductor substrate 110. Specifically, the separation portion protection film 150 is formed on the back surface side of the semiconductor substrate 110 by the same process as the formation of the light blocking film 170. Next, a protection film is disposed on the separation portion protection film 150. Next, it can be formed by disposing the light blocking film 170 at the boundary of the pixel 100.

A in the figure is a diagram showing a configuration example of the pixel 100a. The separation portion protection film 150a and the light blocking film 170a are disposed at a position at which they overlap. That is, the light blocking film 170a is laminated on the separation portion protection film 150a.

B in the figure is a diagram showing a configuration example of the pixel 100b. Due to the pupil correction, the light blocking film 170b is disposed to be shifted and disposed at a position at which it does not overlap the separation portion protection film 150. For this reason, the separation portion protection film 150b and the light blocking film 170b are disposed adjacent to each other in the same layer.

### Other Configurations of Separation Portion Protection Film

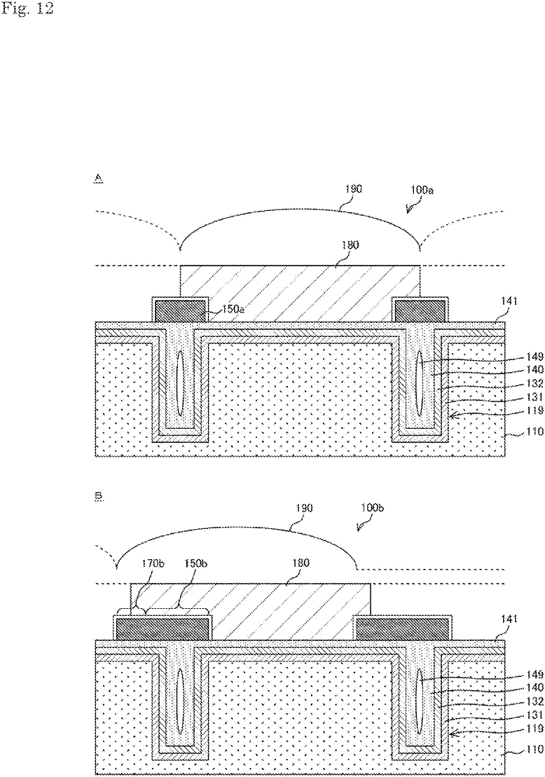

FIG. 12 is a diagram showing other configuration examples of the separation portion protection film according to the third embodiment of the present disclosure. The separation portion protection film 150 in the figure shows an example of being integrally formed with the light blocking film 170.

In the pixel 100a in A of the figure, the light blocking film 170 can be omitted. In the pixel 100b in B of the figure, the light blocking film 170b and the separation portion protection film 150b are integrally formed. That is, the light blocking film 170b and the separation portion protection film 150b in B of the figure are formed in a shape in which the light blocking film 170b and the separation portion protection film 150b in B of FIG. 11 are connected to each other. The light blocking film 170b and the separation portion protection film 150b can be formed at the same time, and the manufacturing process of the imaging element 1 can be simplified.

Since other configurations of the imaging element 1 are the same as those of the imaging element 1 described in the first embodiment of the present disclosure, the description thereof will be omitted.

As described above, in the imaging element 1 of the third embodiment of the present disclosure, the strength of the imaging element 1 can be improved by disposing the separation portion protection film 150 made of a metal.

### 4. Fourth Embodiment

In the imaging element 1 of the first embodiment described above, the separation portion 140 whose end portion reaches the vicinity of the front surface side of the semiconductor substrate 110 has been disposed. On the other hand, an imaging element 1 of a fourth embodiment of the present disclosure is different from the above-mentioned first embodiment in that the separation portion 140 having a shape penetrating the semiconductor substrate 110 is disposed.

### Configuration of Pixels

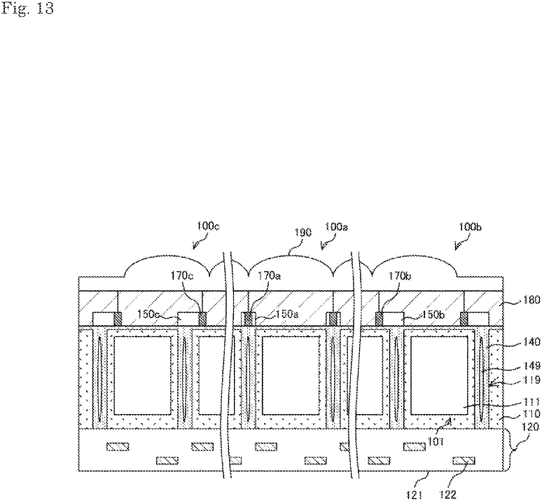

FIG. 13 is a diagram showing a configuration example of pixels according to the fourth embodiment of the present disclosure. Similarly to FIG. 3, the figure is a cross-sectional view showing a configuration example of the pixels 100. It is different from the pixels 100 in FIG. 3 in that the separation portion 140 is formed in a shape penetrating the semiconductor substrate 110.

As described above, the separation portion 140 in the figure is formed in the shape penetrating the semiconductor substrate 110. The opening portion 119 in the figure is formed in the shape penetrating the semiconductor substrate 110. The separation portion 140 is disposed in the opening portion 119. Since the separation portion 140 is configured to penetrate the semiconductor substrate 110, the inflow of charges from the photoelectric conversion units 101 of the adjacent pixels 100 can be further reduced, and the generation of noises can be further reduced. In addition, the opening portion 119 can be formed from the back surface side of the semiconductor substrate. Further, the opening portion 119 can also be formed from the front surface side of the semiconductor substrate 110. In this case, the front surface side of the semiconductor substrate 110 is etched to form the opening portion 119 before the wiring region 120 is disposed.

Even when such a separation portion 140 is disposed, the strength of the pixels 100 can be improved by disposing the separation portion protection film 150.

Since other configurations of the imaging element 1 are the same as those of the imaging element 1 described in the first embodiment of the present disclosure, the description thereof will be omitted.

As described above, in the imaging element 1 of the fourth embodiment of the present disclosure, even in a case in which the separation portion 140 having the shape penetrating the semiconductor substrate 110 is disposed, the strength of the imaging element 1 can be improved by disposing the separation portion protection film 150.

### 5. Example of Application to Camera

The technique according to the present disclosure (the present technique) can be applied to various products. For example, the present technique may be embodied as an imaging element mounted on an imaging device such as a camera.

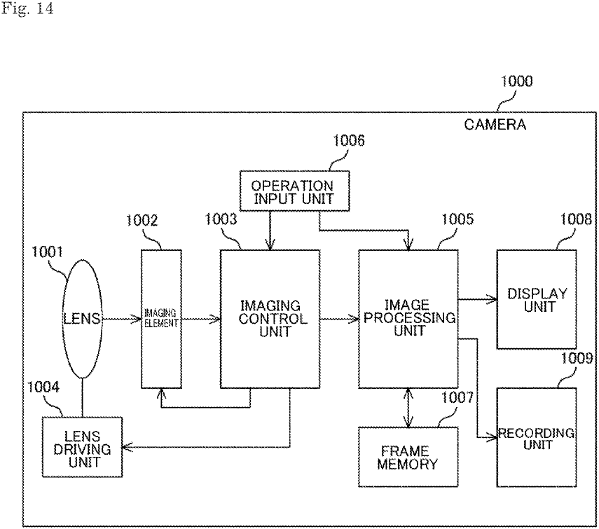

FIG. 14 is a block diagram showing a schematic configuration example of a camera which is an example of the imaging element to which the present technique may be applied. A camera 1000 in the figure includes a lens 1001, an imaging element 1002, an imaging control unit 1003, a lens driving unit 1004, an image processing unit 1005, an operation input unit 1006, a frame memory 1007, a display unit 1008, and a recording unit 1009.

The lens 1001 is a photographing lens of the camera 1000. The lens 1001 condenses light from a subject, causes the light to be incident on the imaging element 1002, which will be described later, and forms an image of the subject.

The imaging element 1002 is a semiconductor element that images the light from the subject condensed by the lens 1001. The imaging element 1002 generates an analog image signal corresponding to radiated light, converts it into a digital image signal, and outputs the signal.

The imaging control unit 1003 controls imaging of the imaging element 1002. The imaging control unit 1003 controls the imaging element 1002 by generating a control signal and outputting the control signal to the imaging element 1002. In addition, the imaging control unit 1003 can perform auto-focus in the camera 1000 on the basis of an image signal output from the imaging element 1002. Here, the auto-focus is a system that detects a focal position of the lens 1001 and automatically adjusts the focal position. For the auto-focus, a method of detecting the focal position by detecting an image plane phase difference with phase difference pixels disposed in the imaging element 1002 (image plane phase difference auto-focus) can be used. In addition, a method of detecting, as a focal position, a position at which a contrast of an image is maximized (contrast auto-focus) can also be applied. The imaging control unit 1003 adjusts the position of the lens 1001 via the lens driving unit 1004 on the basis of the detected focal position and performs the auto-focus. Also, the imaging control unit 1003 can be configured of, for example, a digital signal processor (DSP) equipped with firmware.

The lens driving unit 1004 drives the lens 1001 on the basis of control of the imaging control unit 1003. The lens driving unit 1004 can drive the lens 1001 by changing the position of the lens 1001 using a built-in motor.

The image processing unit 1005 processes an image signal generated by the imaging element 1002. This processing includes, for example, demosaicing for generating an image signal of an insufficient color among image signals corresponding to red, green, and blue for each pixel, noise reducing for removing noises in image signals, image signal encoding, and the like. The image processing unit 1005 can be configured of, for example, a microcomputer equipped with firmware.

The operation input unit 1006 receives an operation input from a user of the camera 1000. For example, a pushbutton or a touch panel can be used as the operation input unit 1006. The operation input received by the operation input unit 1006 is transmitted to the imaging control unit 1003 and the image processing unit 1005. Thereafter, processing corresponding to the operation input, for example, processing such as imaging of a subject is started.

The frame memory 1007 is a memory that stores frames which are image signals corresponding to one screen. The frame memory 1007 is controlled by the image processing unit 1005 and holds the frames during image processing.

The display unit 1008 displays images processed by the image processing unit 1005. For example, a liquid crystal panel can be used for the display unit 1008.

The recording unit 1009 records the images processed by the image processing unit 1005. For example, a memory card or a hard disk can be used for the recording unit 1009.

The camera to which the present disclosure may be applied has been described above. The present technique can be applied to the imaging element 1002 among the constituent elements described above. Specifically, the imaging element 1 described with reference to FIG. 1 can be applied to the imaging element 1002. By applying the imaging element 1 to the imaging element 1002, the strength of the imaging element 1002 can be improved. Also, the image processing unit 1005 is an example of a processing circuit described in the claims. The camera 1000 is an example of an imaging device described in the claims.

Further, the configuration of the pixels 100 of the second embodiment can be combined with other configurations. Specifically, the separation portion protection film 150 in FIG. 10 can be applied to the pixels 100 in FIGS. 11, 12, and 13.

Also, the configuration of the pixels 100 of the third embodiment can be combined with other configurations. Specifically, the separation portion protection film 150 in FIGS. 11 and 12 can be applied to the pixels 100 in FIGS. 10 and 13.

Also, the configuration of the pixels 100 of the fourth embodiment can be combined with other configurations. Specifically, the separation portion 140 in FIG. 13 can be applied to the pixels 100 in FIGS. 10 to 12.

Finally, the description of each embodiment described above is an example of the present disclosure, and the present disclosure is not limited to the above-described embodiments. For this reason, it is needless to say that various changes aside from the above-described embodiments can be made according to the design and the like within a scope of not departing from the technical idea of the present disclosure.

Also, the effects described in the present specification are merely examples and are not intended as limiting. Other effects may be obtained as well.

In addition, the figures in the above-described embodiments are schematic, and dimensional ratios and the like of respective parts are not necessarily consistent with actual ones. Also, the figures of course include parts where dimensional relationships and ratios differ from drawing to drawing.

Further, the present technique can also have the following configurations.
(1) An imaging element including:
   a plurality of pixels including photoelectric conversion units that are formed on a semiconductor substrate and perform photoelectric conversion of incident light;
   separation portions that are disposed at boundaries of the plurality of pixels and separate the photoelectric conversion units from each other;
   light blocking films that are disposed near the boundaries of the plurality of pixels and block the incident light; and
   separation portion protection films that are disposed adjacent to the separation portions and protect the separation portions.
(2) The imaging element according to the above (1), wherein the separation portions are disposed in opening portions formed in the semiconductor substrate.
(3) The imaging element according to the above (2), wherein the separation portions include an insulating material disposed in the opening portions.
(4) The imaging element according to any one of the above (1) to (3), wherein voids are disposed in the separation portion protection films.
(5) The imaging element according to any one of the above (1) to (4), further including color filters that are disposed in the plurality of pixels and transmit incident light having predetermined wavelengths among the incident lights.
(6) The imaging element according to any one of the above (1) to (5), further including on-chip lenses that are disposed in the plurality of pixels and condense the incident light on the photoelectric conversion units.
(7) The imaging element according to any one of the above (1) to (6), wherein the light blocking films are disposed at shifted positions in accordance with angles of incidence of the incident light.
(8) The imaging element according to any one of the above (1) to (7), wherein the separation portion protection films are disposed adjacent to the light blocking films.
(9) The imaging element according to the above (8), wherein the light blocking films are disposed to overlap the separation portion protection films.
(10) The imaging element according to any one of the above (1) to (9), wherein the pixels are formed in rectangular shapes in a plan view.
(11) The imaging element according to the above (10), wherein the separation portion protection films are disposed near sides of the rectangular shapes.
(12) The imaging element according to the above (10), wherein the separation portion protection films are disposed near corners of the rectangular shapes.
(13) The imaging element according to any one of the above (1) to (12), wherein the separation portion protection films are made of an insulating material.
(14) The imaging element according to the above (13), wherein the separation portion protection films are made of a silicon compound.
(15) The imaging element according to the above (13), wherein the separation portion protection films are made of a resin.
(16) The imaging element according to any one of the above (1) to (15), wherein the separation portion protection films are made of a metal.
(17) An imaging device including:
   a plurality of pixels including photoelectric conversion units that are formed on a semiconductor substrate and perform photoelectric conversion of incident light;
   separation portions that are disposed at boundaries of the plurality of pixels and separate the photoelectric conversion units from each other;
   light blocking films that are disposed near the boundaries of the plurality of pixels and block the incident light;
   separation portion protection films that are disposed adjacent to the separation portions and protect the separation portions; and
   a processing circuit that processes image signals generated on the basis of the photoelectric conversion.

### Reference Sings List

1, 1002 Imaging element
10 Pixel array unit
30 Column signal processing unit
100, 100a, 100b, 100c, 100d Pixel
101 Photoelectric conversion unit
119 Opening portion
132 Insulating film
140 Separation portion
141 Protection film
149 Void
150, 150a, 150b, 150c, 150d, 151, 151a, 151d, 152a, 152d Separation portion protection film
170, 170a, 170b, 170c, 170d, 171, 171a, 171d, 172, 172a, 172d Light blocking film
180, 180a, 180b, 180c Color filter
190, 190a, 190b, 190c On-chip lens
1000 Camera
1005 Image processing unit

What is claimed is:

1. An imaging element, comprising:
a plurality of pixels including photoelectric conversion units that are formed on a semiconductor substrate and perform photoelectric conversion of incident light;
separation portions that are disposed at boundaries of the plurality of pixels and separate the photoelectric conversion units from each other;
light blocking films that are disposed near the boundaries of the plurality of pixels and block the incident light; and
separation portion protection films that are disposed adjacent to the separation portions and protect the separation portions.

2. The imaging element according to claim 1, wherein the separation portions are disposed in opening portions formed in the semiconductor substrate.

3. The imaging element according to claim 2, wherein the separation portions include an insulating material disposed in the opening portions.

4. The imaging element according to claim 1, wherein voids are disposed in the separation portion protection films.

5. The imaging element according to claim 1, further comprising color filters that are disposed in the plurality of pixels and transmit incident light having predetermined wavelengths among the incident lights.

6. The imaging element according to claim 1, further comprising on-chip lenses that are disposed in the plurality of pixels and condense the incident light on the photoelectric conversion units.

7. The imaging element according to claim 1, wherein the light blocking films are disposed at shifted positions in accordance with angles of incidence of the incident light.

8. The imaging element according to claim 1, wherein the separation portion protection films are disposed adjacent to the light blocking films.

9. The imaging element according to claim 8, wherein the light blocking films are disposed to overlap the separation portion protection films.

10. The imaging element according to claim 1, wherein the pixels are formed in rectangular shapes in a plan view.

11. The imaging element according to claim 10, wherein the separation portion protection films are disposed near sides of the rectangular shapes.

12. The imaging element according to claim 10, wherein the separation portion protection films are disposed near corners of the rectangular shapes.

13. The imaging element according to claim 1, wherein the separation portion protection films are made of an insulating material.

14. The imaging element according to claim 13, wherein the separation portion protection films are made of a silicon compound.

15. The imaging element according to claim 13, wherein the separation portion protection films are made of a resin.

16. The imaging element according to claim 1, wherein the separation portion protection films are made of a metal.

17. An imaging device, comprising:
a plurality of pixels including photoelectric conversion units that are formed on a semiconductor substrate and perform photoelectric conversion of incident light;
separation portions that are disposed at boundaries of the plurality of pixels and separate the photoelectric conversion units from each other;
light blocking films that are disposed near the boundaries of the plurality of pixels and block the incident light;
separation portion protection films that are disposed adjacent to the separation portions and protect the separation portions; and
a processing circuit that processes image signals generated on the basis of the photoelectric conversion.
